(19) United States
(12) Patent Application Publication
(10) Pub. No.: US 2010/0068480 A1
(43) Pub. Date: Mar. 18, 2010

(54) Negative-working photosensitive resin composition and photosensitive resin plate using the same

(76) Inventors: Hiroshi Takanashi, Tokyo (JP); Tomoya Kudo, Kanagawa-ken (JP)

Correspondence Address: WENDEROTH, LIND & PONACK, L.L.P., 1030 15th Street, N.W.,, Suite 400 East, Washington, DC, 20005-1503, US

(21) Appl. No.: 12/591,301

(22) Filed: Nov. 16, 2009

Related U.S. Application Data
(63) Continuation of application No. 11/822,414, filed on Jul. 5, 2007, now abandoned.
Application No. 11/822,414 is a continuation of application No. 11/504,080, filed on Aug. 15, 2006, now abandoned.
Application No. 11/504,080 is a continuation of application No. 11/263,847, filed on Nov. 2, 2005, now abandoned.
Application No. 11/263,847 is a continuation of application No. 09/838,118, filed on Apr. 20, 2001, now abandoned.
Application No. 09/838,118 is a division of application No. 09/262,077, filed on Mar. 4, 1999, now abandoned.

(30) Foreign Application Priority Data
Mar. 5, 1998 (JP) 71513/1998

(51) Int. Cl. G03F 7/004; B32B 5/00

(52) U.S. Cl. 428/195.1; 430/281.1; 430/283.1

(57) ABSTRACT

A negative-working photosensitive resin composition is disclosed, comprising (A) a film-forming polymer, (B) an unsaturated compound having a radical polymerizable ethylenic double bond, (C) a photopolymerization initiator, and (D) a thermal polymerization inhibitor, wherein the resin composition further contains (E) at least one member selected from compounds represented by following formula (I):

R¹—X (I)

wherein —X represents —OR², —COOH, —SO₃H, —CONHR², —COR², —SO₂NHR², —HNCONHR², or —HNCOOR²; R¹ and R², which may be the same or different, each represents a hydrogen atom, a substituted or unsubstituted, saturated or unsaturated hydrocarbon group, provided that it does not contain a radical polymerizable ethylenic double bond, a substituted or unsubstituted alicyclic hydrocarbon group, a substituted or unsubstituted aromatic hydrocarbon group, or a heterocyclic group; they may have an ether bond in the chain, provided that when —X is —OH, then R¹ represents a group other than a hydrogen atom and an aromatic hydrocarbon group, in a range of 0.001-0.3 wt % based on the weight of the photosensitive resin composition. A photosensitive resin plate using the photosensitive resin composition is also disclosed. By this invention, a negative-working photosensitive resin composition particularly excellent in the reproducibility of the highlight areas and the independent fine lines and having the deep non-printing depth and good resolving properties, and a photosensitive resin plate using the resin composition are provided.

This is a continuation of Ser. No. 09/838,118, filed Apr. 20, 2001, now abandoned, which is a divisional of Ser. No. 09/262,077, filed Mar. 4, 1999, now abandoned.

### BACKGROUND OF THE INVENTION

1. Field of the Invention

This invention relates to a negative-working photosensitive resin composition utilized for various printing fields and to a photosensitive resin plate using it. More specifically, this invention relates to a negative-working photosensitive resin composition which is excellent in reproducibility of particularly, highlight areas and independent fine lines, has deep depth of non-printing areas (hereinafter, is referred to non-printing depth), and has good resolving properties, and to a photosensitive resin plate using the resin composition.

2. Description of the Related Art

As photosensitive resin compositions used for photosensitive resin plates (printing plates) utilized in the printing fields such as book printing, slip printing, general printing, seal printing, original plates for making mother patterns of seals, flexo printing, dry offset printing, etc., water-soluble, alkali-soluble, or alcohol-soluble negative-working photosensitive resin compositions are known. As the photosensitive resin compositions used for these printing plates, a photosensitive resin composition excellent in reproducibility of highlight areas and independent fine lines and having deep non-printing depth has been being desired.

Particularly, recently, with the development of information-oriented society, the requirements for the improvement of the quality of various prints have been increased. For example, in a photosensitive resin plate used for seal printing, the reproducibility of a highlight of 2-3% at 133 lines/inch (showing that a ratio of the light-transmitting areas to the total area of the light-shielding areas and the light-transmitting areas of a negative film is 2-3% and that the light-shielding areas are formed by an assembly of dots each having a width of 1/133 inch), and of independent fine lines of a line width of about 10-20 μm has been required. Thus, in the photosensitive resin plates used for printing, the improvement of the reproducibility of fine patterns has been more and more desired.

In order to produce such a printing plate having the reproducibility of a highlight and independent fine lines, it is necessary to increase an exposure amount at making a photosensitive resin plate to sufficiently carry out photocuring reaction of a photosensitive resin. However, in conventional negative-working photosensitive resin compositions, there are problems that the exposure latitude (exposure width) is not sufficient, with the increase of the exposure amount, the photocuring reaction at unexposed areas of a photosensitive layer corresponding to light-shielding areas of a negative film proceeds, whereby the depth of non-printing areas and halftone dots areas becomes greatly shallow.

When a photosensitive resin plate having a shallow depth is used as a printing plate, there occurs a problem that the non-printing areas and the halftone dots dark areas are clogged with an ink, whereby areas which should be essentially non-printed can not be reproduced by blackening with an ink, or prints having a dark tone are obtained.

Thus, as an attempt of broadening the exposure width, a photosensitive resin plate having a double-layered photosensitive layer each having a different sensitivity (see JP-A-55-6392 and JP-A-2-970), a photosensitive resin composition containing a compound forming a light-absorptive substance upon light exposure (see JP-A-50-122302), a photosensitive resin plate composed of a photosensitive layer containing N-nitrosodiphenylamine and an adhesive layer containing a Michler's ketone (see JP-A-57-93342), etc., are proposed.

Also, a photosensitive resin composition containing a compound selected from isoalloxazines and alloxazines and a compound selected from N-nitrosodiphenylamine, N-nitrosocyclohexylhydroxylamine and hydroquinone monomethyl ether (see JP-A-3-2757), a photosensitive resin composition obtained by adding an azo dye to a photosensitive composition using a styrene-butadiene block copolymer, etc. (see JP-A-5-273752), a method of improving transparency of a photosensitive layer by heat treating a photosensitive composition containing a crystalline polymer at a temperature of 40-120° C. (see JP-A-59-123836), etc., are proposed.

A negative-working photosensitive resin composition typically comprises a combination of a film-forming polymer, a radical polymerizable unsaturated compound, and a photopolymerization initiator, and where it sometimes happens that by an oozing phenomenon of the unsaturated compound from the photosensitive resin composition, the surface of a photosensitive layer, which is formed by the photosensitive composition, becomes tacky and thus, as the case may be, there occurs a problem that in intimate contact of a negative film (mask pattern) with the surface of the photosensitive layer at exposure, by the influence of air confined between the negative film and the photosensitive layer, images (photocured patterns) become indistinct, and also, the halftone dots depth and the non-printing area depth become shallow.

In view of the matter that the reproduction of fine patterns relates to the state of intimate contact of a negative film with the surface of a photosensitive layer at exposure as described above, an attempt of improving the reproducibility of fine patterns by improving surface properties of a photosensitive layer is reported, and, for example, a sticking prevention method by matting the surface of a photosensitive layer (see JP-A-50-31488, JP-A-63-146045, JP-A-5-313356, etc.), a slip coating method for sticking prevention by leaving a resin, which is hard to stick to a negative film, on the surface of a photosensitive layer (see JP-A-5-232708, JP-A-5-27419, JP-A-4-359256, JP-A-51-49803, JP-A-58-18633, JP-A-57-34557, JP-A-9-71765, JP-A-5-297594, etc.), etc., are proposed.

Also, an attempt of a three-layered mat cover, etc. , is reported (JP-A-63-259552).

However, in the present printing industry, a far higher quality is being demanded, and negative-working photosensitive resin compositions sufficiently meeting these requirements have not yet been realized.

As a result of various investigations for solving the above-described problems, the inventors have discovered that the above-described problems can be solved by incorporating a definite amount of a compound having a specific polar group to a radical polymerization-type negative-working photosensitive resin composition and, particularly, a photosensitive resin plate having a deep non-printing depth is obtained even by increasing the exposure amount, leading to accomplishment of this invention.

### SUMMARY OF THE INVENTION

This invention has been made in view of the above-described circumstances. Thus, an object of this invention is to provide a negative-working photosensitive resin composition which is excellent in reproducibility of highlight areas and independent fine lines having a line width of about 10-20 μm, does not make the non-printing depth shallow even by increasing the exposure amount at plate making, and has an improved exposure width, as well as a photosensitive resin plate using the resin composition.

That is, this invention provides a negative-working photosensitive resin composition comprising (A) a film-forming polymer, (B) an unsaturated compound having a radical polymerizable ethylenic double bond, (C) a photopolymerization initiator, and (D) a thermal polymerization inhibitor, wherein the resin composition further contains (E) at least one member selected from compounds represented by following formula (I):

R¹—X (I)

wherein —X represents —OR², —COOH, —CONHR², —COR², —SO₂NHR², —HNCONHR², or —HNCOOR²; R¹ and R², which may be the same or different, each represents a hydrogen atom, a substituted or unsubstituted, saturated or unsaturated hydrocarbon group, provided that it does not contain a radical polymerizable ethylenic double bond, a substituted or unsubstituted alicyclic hydrocarbon group, a substituted or unsubstituted aromatic hydrocarbon group, or a heterocyclic group; they may have an ether bond in the chain, provided that when —X is —OH, then R¹ represents a group other than a hydrogen atom and an aromatic hydrocarbon group, in a range of 0.001-0.3 wt % based on the weight of the photosensitive resin composition.

Also, this invention provides a photosensitive resin plate (raw plate or to-be-exposed plate) comprising a support having thereon a photosensitive layer comprising the above-described negative-working photosensitive resin composition directly or via an adhesive layer.

Furthermore, this invention provides a photosensitive resin plate having formed thereon photocured images obtained by selectively exposing the photosensitive layer on the above-described photosensitive resin plate through a mask pattern, developing, and forming the photocured images by removing the unexposed areas.

### DETAILED DESCRIPTION OF THE INVENTION

The negative-working photosensitive resin composition of this invention and the photosensitive resin plate using it are hereunder described in detail.

As the film-forming polymer (A), water-soluble polymers, alkali-soluble polymers, and alcohol-soluble polymers are preferably used.

### (A-1) Water-Soluble Polymer:

As the water-soluble polymer used in this invention, any polymers which are dissolved in an ordinary water having a pH of from about 5 to 8 can be used without specific restrictions. Specific examples include polyvinyl alcohol, N-methylolacrylamide-added polyvinyl alcohol, denatured polyvinyl alcohols (such as a polyvinyl alcohol/polyacrylate block copolymer, denatured polyvinyl alcohol having acrylic anhydride reacted therewith, and grafted polyvinyl alcohol), carboxyalkyl celluloses, polyamides having a sodium sulfonate group, a polyamide having an ether bond, a polyamide having basic nitrogen or ammonium salt-type nitrogen, and polyvinyl pyrrolidone, but the water-soluble polymer used in this invention is not limited to these polymers. Among these polymers, polyvinyl alcohol is suitably used because it is relatively inexpensive. The water-soluble polymers may be used singly or as a combination of two or more thereof.

### (A-2) Alkali-Soluble Polymer:

As the alkali-soluble polymer used in this invention, polymers which are dissolved or dispersed in an aqueous alkaline solution having a pH of about 8 or higher can be used without particular restrictions, and examples include polymers having a group such as —COOH, —PO₃H₂, —SO₃H, —SO₂NH₂, —SO₂NHSO₂—, and SO₂—NH—CO—.

Specific examples of the polymer include maleic anhydride-denatured polybutadiene, a carboxyl group-containing styrene-butadiene copolymer, a maleic ester resin, a polymer of β-methacryloyloxyethyl-N-(p-trisulfonyl)carbamate, copolymers of monomers similar to the monomers constituting these polymers and other monomers, a vinyl acetate/crotonic acid copolymer, a styrene/maleic anhydride copolymer, a methacrylic ester/methacrylic acid copolymer, a methacrylic acid/styrene/acrylonitrile copolymer, and cellulose acetate phthalate, but the alkali-soluble polymers used in this invention are not limited to these polymers. Among these polymers, cellulose acetate phthalate is preferably used in view of transparency and solubility. The alkali-soluble polymers may be used singly or as a combination of two or more thereof.

### (A-3) Alcohol-Soluble Polymer:

As the alcohol-soluble polymer used in this invention, alcohol-soluble nylons are preferred. Specific examples include 8 nylon, 6 nylon/66 nylon, 6 nylon/66 nylon/610 nylon, 6 nylon/66 nylon/610 nylon/612 nylon, and a 4,4′-diaminodicyclohexylmethane/hexamethylenediamine/adipic acid/ε-caprolactam copolymer, but the invention is not limited to these polymers. Among these polymers, 8 nylon and 4,4′-diaminodicyclohexylmethane/hexamethylenediamine/adipic acid/ε-caprolactam copolymer are preferably used in view of transparency and solubility. The alcohol-soluble polymers may be used singly or as a combination of two or more thereof.

The content of the component (A) is preferably 15-70 wt %, more preferably 20-65 wt %, and particularly preferably 25-60 wt % of the total solid components of the photosensitive resin composition of this invention. If the content exceeds the above-described range, troubles that the faculty of washing out unexposed areas is lowered, the photocuring reaction of exposed areas does not sufficiently proceed, etc. On the other hand, if the content is less than the above-described range, there is a tendency that a cold flow phenomenon in which at high temperatures the photosensitive resin plate is deformed and does not reflect a raw plate's form, i. e., a to-be-exposed photosensitive resin plate's form.

As the unsaturated compound (B) having a radical polymerizable ethylenic double bond, unsaturated compounds generally used for photosensitive resin compositions can be used without particular restrictions. Specific examples include ethylene glycol-mono(meth)acrylate, diethylene glycol mono(meth)acrylate, propylene glycol mono(meth)acrylate, polyethylene glycol mono(meth)acrylate, polypropylene glycol mono(meth)acrylate, polyethylene glycol monomethoxymonoacrylate, N-methylolacrylamide, N-ethylolacrylamide, N-propylolacrylamide, N-methylol(meth)acrylamide, N-ethylol(meth)acrylamide, N-propylolmethacrylamide, diacetoneacrylamide, hydroxypropyl acrylate, triacrylformal, diacrylamide dimethylene ether, methylene bisacrylamide, ethylene glycol di(meth)acrylate, diethylene glycol di(meth)acrylate, triethylene glycol di(meth)acrylate, tetraethylene glycol di(meth)acrylate, polyethylene glycol di(meth)acrylate, trimethylolpropane tri(meth)acrylate, trimethylolpropane di(meth)acrylate, oligourethane di(meth)acrylate, 1,3-butanediol di(meth)acrylate, 1,4-butanediol di(meth)acrylate, 1,6-hexanediol di(meth)acrylate, pentaerythritol tetra(meth)acrylate, pentaerythritol tri(meth)acrylate, triacrylformal, and an adduct of a bisepoxy compound and acrylic acid. The unsaturated compounds having a radical polymerizable ethylenic double bond may be used singly or as a combination of two or more thereof.

The content of the component (B) is preferably 20-50 wt %, and more preferably 25-45 wt % of the total solid components of the photosensitive resin composition of this invention. If the component exceeds the above-described range, there is a tendency that the compound causes phase separation and oozes during storing the photosensitive resin plate. On the other hand, if the content is less than the above-described range, there is a tendency of lowering the reproducibility of images.

As the photopolymerization initiator (C), there are no particular restrictions, and conventionally known ones can be optionally used. Specific examples include benzophenone derivatives such as benzophenone and 2-hydroxy-4-alkoxybenzophenone; benzoin derivatives such as benzoin, benzoin isopropyl ether, benzoin methyl ether, benzoin ethyl ether, and benzoin isobutyl ether; xanthone derivatives such as xanthone, thioxanthone, and 2-ethylthioxanthone; anthraquinone derivatives such as anthraquinone, methylanthraquinone, ethylanthraquinone, carboxyanthraquinone, sodium 2,6-anthraquinonedisulfonate, and sodium 2,7-anthraquinonedisulfonate; benzyl dimethyl ketal; acetophenone; and 2,2-diethoxyacetophenone, but the component (C) used in this invention is not limited to these compounds. The photopolymerization initiators may be used singly or as a combination of two or more thereof.

The content of the component (C) is preferably 0.5-5 wt %, and more preferably 1-4 wt % of the total solid components of the photosensitive resin composition of this invention. If the content exceeds the above-described range, a trouble that the increase of the ultraviolet absorption by the component (C) itself makes the photocuring reaction in a lower portion of the image not sufficiently proceed is liable to occur. On the other hand, if the content thereof is less than the above-described range, there is a tendency that the reproducibility of the fine lines and independent dots is deteriorated.

The thermal polymerization inhibitor (D) is used for not only restraining the occurrence of the polymerization reaction of the composition during stirring under heating but also improving the storage stability of photosensitive resin plates after the production. There are no particular restrictions on the thermal polymerization inhibitor and conventionally known ones can be optionally used. Specific examples include quinone derivatives such as hydroquinone, methylhydroquinone, and p-benzoquinone; phenol derivatives such as 2,6-di-tert-butyl-p-cresol; and nitrobenzene or derivatives thereof, but the component (D) used in this invention is not limited to these compounds. The thermal polymerization inhibitors may be used singly or as a combination of two or more thereof.

The content of the component (D) is preferably 0.01-1 wt % of the total solid components of the photosensitive resin composition of this invention. If the content exceeds the above-described range, a trouble of lowering the sensitivity at using the photosensitive resin plate is liable to occur. On the other hand, if the content is less than the above-described range, there is a tendency that the restraint of the polymerization reaction and the storage stability are deteriorated.

In this invention, in addition to the above-described components (A) to (D), it is necessary that (E) at least one member selected from compounds represented by the following formula (I):

R¹—X (I)

wherein —X represents —OR², —COOH, —SO₃H, —CONHR², —COR², —SO₂NHR², —HNCONHR², or —HNCOOR²; R¹ and R², which may be the same or different, each represents a hydrogen atom, a substituted or unsubstituted, saturated or unsaturated hydrocarbon group, provided that it does not contain a radical polymerizable ethylenic double bond, a substituted or unsubstituted alicyclic hydrocarbon group, a substituted or unsubstituted aromatic hydrocarbon group, or a heterocyclic group; they may have an ether bond in the chain, provided that when —X is —OH, then R¹ represents a group other than a hydrogen atom and an aromatic hydrocarbon group, is contained in the photosensitive resin composition in a range of 0.001-0.3 wt %, and preferably 0.002-0.25 wt %.

In general, in the production of a printing plate using a radical polymerization-type negative-working photosensitive resin composition, the depth and resolution of the image (relief) are strongly influenced by oxygen at the irradiation of light and are determined by the balance of the diffusing amount of oxygen retained between the surface of a photosensitive layer comprising a photosensitive resin composition formed on a support and a negative film (mask pattern) into the photosensitive layer, and the radical generating amount in the inside of the photosensitive layer.

Because oxygen diffused into the photosensitive layer acts as a radical polymerization inhibitor to show a desensitizing action, when the amount of oxygen retained between the negative film and the surface of the photosensitive layer is small, the desensitizing action by oxygen is small, and the non-printing depth becomes shallow. On the other hand, the amount of oxygen is high, the sensitivity is lowered, and the form of the image areas is deteriorated.

Accordingly, in order to improve the non-printing depth without lowering the sensitivity, it is necessary to properly take oxygen between the negative film and the surface of the photosensitive layer in the photosensitive layer.

On the other hand, it is known by experience that in the negative-working photosensitive resin plate using a film-forming polymer soluble in an alcohol, water, or an aqueous alkaline solution, when about 3 to 7 days passes after the production, the “Step Tablet” (Eastman Kodak Corporation) sensitivity increases by from 1 to 2 steps. This is considered to be caused by the fact that by forming a three-dimensional network structure of hydrogen bonds by the polar groups in the components (A) and (B) in the photosensitive resin composition, that is, by crystallization, the diffusion of oxygen into the photosensitive layer at the irradiation of light is prevented, and the desensitizing action by oxygen is restrained.

In this invention, it is considered that by incorporating the above-described specific amount of the component (E) in the photosensitive resin composition, not only the three-dimensional network structure by the hydrogen bonds in the photosensitive resin composition is destroyed, but also the diffusing amount of oxygen into the photosensitive layer can be properly controlled. Thus, the radical generating amount and the diffusing amount of oxygen at the irradiation of light can be balanced well; and the negative-working photosensitive resin composition excellent in the reproducibility of the highlight areas and the fine patters of independent fine lines, particularly having a deep non-printing depth even by increasing the exposure amount at plate making and having an improved exposure width, is realized.

As the reasons, it is considered that the compound represented by the formula (I) has only one polar group in the structure, and the one polar group approaches the hydrogen bond portion of the photosensitive resin composition, and by incorporation of non-polar portions of the compound into the hydrogen-bonded portion of the resin composition, the hydrogen bond in the photosensitive resin composition is hindered to destroy the network structure, whereby oxygen becomes liable to diffuse. Also, it is considered that oxygen diffused in the resin traps radicals generated by the irradiation of light at exposure, whereby the occurrence of the polymerization reaction on the surface of the photosensitive layer is restrained, and lowering the non-printing depth is restrained even by increasing the exposure amount.

The polar group as referred to in this invention is —OR², —COOH, —SO₃H, —CONHR², —COR², —SO₂NHR², —HNCONHR², or —HNCOOR² (wherein R² is as defined above), and it is necessary that only one polar group exists in the compound. If two or more polar groups exist in the compound, they supplement the network structure by the hydrogen bonds in the photosensitive resin composition, whereby not only the effect of destroying the network structure, but also the non-printing depth is made shallow.

The content of the component (E) is 0.001-0.3 wt %, and preferably 0.002-0.25 wt % based on the weight of the photosensitive resin composition.

When the component (E) has high compatibility with the photosensitive resin composition, if its content exceeds the above-described range, the component (E) elutes out from the photocured areas (imaged areas) at washing out (development) of the unexposed areas, and also, the strength of the photocured areas is lowered, whereby the photocured areas are scratched at washing out using a brush, and the halftone dots and fine lines are broken. Also, in spray development, because a brush is not used at washing out, though the photocured areas are not scratched, by elution of the component (E) from the photocured areas, the film at the halftone highlight and the fine lines is reduced, and the photosensitive resin plate is inferior in aptitude as a printing plate material.

On the other hand, when the component (E) has low compatibility with the photosensitive resin composition, if its content exceeds the above-described range, the component (E) is separated from the photosensitive layer and deposited before exposure, the photosensitive layer becomes opaque to cause scattering of light, and the non-printing depth is made shallow.

Also, because the compounding amount of the compound (E) is slight, phenomena of transferring the component (E) onto the surface of the photosensitive layer and of rising of the component (E) on the surface are not observed.

In addition, though the photosensitive resin compositions each containing a compound having a —CONH— group or —COOH— group are reported (see JP-A-59-149354 and JP-A-61-267055), in the ranges of the addition amounts of the compounds described in these patent publications, the diffusing amount of oxygen into the photosensitive layer is, on the contrary, reduced, and the effect of this invention cannot be obtained.

When the compound represented by the formula (I) has an ether bond(s) in the structure, it is preferred that the number of ether bonds is from 1 to 5, and particularly from 1 to 3. Specific examples include monomethyl ether of ethylene glycol and monoethyl ether of ethylene glycol. The monoalkyl ether of polyethylene glycol having more than five ether bonds tend to make the non-printing depth shallow.

In addition, a compound having an amino group such as —NH₂ and ═NH, which is generally known to be a polar group, for example, an aliphatic amino group-having compound, causes Michel addition condensation with the unsaturated compound having a radical polymerizable ethylenic double bond (for example, a (meth)acryl compound), and the non-printing depth is undesirably made shallow.

Also, the —OH group which is one of the polar groups used in this invention, when it bonds directly to an aromatic nucleus, becomes a radical polymerization inhibitor, whereby the lowering of the sensitivity becomes undesirably large.

It is indispensable that the compound represented by the formula (I) does not have a radical polymerizable ethylenic double bond in the molecule. When the compound has a radical polymerizable ethylenic double bond in the molecule, because not only a network structure is formed by the polymerization reaction of the double bond, but also the compound is taken into the hydrogen bond in the resin due to the presence of the polar group, the effect of destroying the network structure in the photosensitive resin composition is not obtained, and oxygen cannot be diffused into the resin. Examples of the radical polymerizable ethylenic double bond are a double bond directly bonded to a polar group such as a carbonyl group, and specifically, acrylamide, acrylic acid, methacrylic acid, hydroxyethyl(meth)acrylate, hydroxypropyl(meth)acrylate, etc.

By the addition of the component (E), the above-mentioned advantageous effects of this invention are obtained. Furthermore, it shall be specifically noted that a defect in the conventional technology that in winter (a dry season), a photosensitive resin plate using a polar polymer such as polyvinyl alcohol, is liable to be cracked can be improved. It is considered that such an advantageous effect is obtained by destroying the network structure by the hydrogen bonds in the resin by the addition of the component (E).

As the compounds represented by the formula (I), there are, for example, the following compounds.

(E-1) Monohydric Alcohols and Ethers (when —X is —OR²):

### (E-1-1) Alcohols:

### (E-1-1-1) Saturated Alcohols:

For example, 1-undecanol, 1-ethoxy-2-propanol, 1-octanol, 1-decanol, 1-dodecanol, 1-nonanol, 1-butanol, 1-propanol, 1-hexanol, 1-heptanol, 1-pentanol, 1-methoxy-2-propanol, 2,2-dimethylpropanol, 2-(methoxymethoxy)ethanol, 2-isopropoxy ethanol, 2-isopentyloxy ethanol, 2-ethyl-1-butanol, 2-ethyl-1-hexanol, 2-octanol, 2-butanol, 2-heptanol, 2-pentanol, 2-methyl-1-butanol, 2-methyl-1-pentanol, 3,5,5-trimethyl-1-hexanol, 3-heptanol, 3-pentanol, 3-methyl-1-butanol, 3-methyl-2-butanol, 4-methyl-2-pentanol, n-hexanol, n-eicosyl alcohol, n-octacosyl alcohol, n-tetradecyl alcohol, n-triacontyl alcohol, n-hexacosyl alcohol, t-isopentyl alcohol, isobutyl alcohol, isopentyl alcohol, diacetone alcohol, dipropylene glycol monomethyl ether, stearyl alcohol, cetyl alcohol, neopentyl alcohol, pentamethylethyl alcohol, methylvinylcarbinol, melissyl alcohol, etc.

### (E-1-1-2) Unsaturated Alcohols:

### (E-1-1-2-1) Ethylenic Unsaturated Alcohols:

For example, allylcarbinol, cis-crotyl alcohol, trans-crotyl alcohol, allyl alcohol, methylpropenyl carbinol, oleyl alcohol, 4-penten-1-ol, 2-methyl-4-penten-2-ol, 10-undecen-1-ol, 9-octadecen-1-ol, citronellol, cis-hexenol, etc.

### (E-1-1-2-2) Acetylenic Unsaturated Alcohols:

For example, propargyl alcohol, 3-methyl-1-pentin-3-ol, 2-hexyn-1-ol, 2-methyl-3-butyn-2-ol, 2-pentyn-1-ol, 3-butyn-1-ol, 2-butyn-1-ol, 3-butyn-2-ol, etc.

### (E-1-1-2-3) Diolefinic Unsaturated Alcohols:

For example, 2,4-hexadien-1-ol, 3,5-hexadien-2-ol, 1,4-hexadien-3-ol, 2,4-pentadien-1-ol, 1,4-pentadien-3-ol, etc.

### (E-1-1-2-4) Other Unsaturated Alcohols:

For example, 2,4-pentadiyn-1-ol, 2,4,6-octatrien-1-ol, 2-methyl-5-hexen-3-yn-2-ol, tripropinyl carbinol, 2,4,6,8,10-dodecapentaen-1-ol, 2-methyl-3-hexen-5-yn-2-ol, 4-hexen-1-yn-3-ol, 2,4,6,8-decatetraen-1-ol, 3-hexen-5-yn-2-ol, 5-methyl-4-hexen-1-yn-3-ol, tri(tert-butenyl)carbinol, 5,7-octadiyn-4-ol, 3,5-hexadiyn-2-ol, etc.

### (E-1-1-3) Alcohols Having an Ether Bond in the Chain:

For example, 2-methoxyethanol, a polyglycol ether (a condensate of a higher alcohol and ethylene oxide), tripropylene glycol monomethyl ether, diethylene glycol monomethyl ether, 2-hexyloxyethanol, 2-ethoxyethanol, 2-phenoxyethanol, diethylene glycol monoethyl ether, 2-butoxyethanol, diethylene glycol monobutyl ether, dipropylene glycol monoethyl ether, triethylene glycol monomethyl ether, etc.

### (E-1-1-4) Alcohols Having an Aromatic Hydrocarbon Group or a Heterocyclic Group:

For example, tetrahydrofurfuryl alcohol, furfuryl alcohol, 2-benzyloxyethanol, benzyl alcohol, cinnamic alcohol, 2-phenoxyethanol dimethylbenzylcarbinol, phenylethyl alcohol, etc.

### (E-1-1-5) Alcohols Having an Alicyclic Hydrocarbon Group:

For example, 2-ethylcyclohexanol, 3-methylcyclohexanol, 1-methylcyclohexanol, 4-methylcyclohexanol, 2-methylcyclohexanol, cyclohexanol, etc.

### (E-1-2) Ethers:

For example, methyl-n-amyl ether, ethyl-n-butyl ether, diisopropyl ether, methyl-n-hexyl ether, ethyl-n-hexyl ether, benzyl ethyl ether, ethyl-n-amyl ether, ethyl neopentyl ether, n-propyl isobutyl ether, isopropyl-n-butyl ether, di-n-butyl ether, diisoamyl ether, benzyl ethyl ether, etc.

(E-2) Monohydric Carboxylic Acids (when —X is —COOH):

### (E-2-1) Saturated Carboxylic Acids:

For example, formic acid, acetic acid, propionic acid, butyric acid, valerianic acid, caproic acid, heptanoic acid, caprylic acid, pelargonic acid, capric acid, n-undecanoic acid, lauric acid, n-tridecanoic acid, myristic acid, n-pentadecanoic acid, palmitic acid, margarinic acid, stearic acid, n-nonadecanoic acid, arachidinoic acid, n-heneicosanoic acid, behenic acid, n-tricosanoic acid, lignoceric acid, n-pentacosanoic acid, cerotic acid, n-heptacosanoic acid, montanic acid, n-nonacosanoic acid, melissic acid, n-hentriacontanoic acid, n-dotriacontanoic acid, n-tetratriacontanoic acid, ceroplastic acid, n-hexatriacontanoic acid, n-octatriacontanoic acid, n-hexatetracontanoic acid, isobutyric acid, isovalerianic acid, methylethylacetic acid, pi-valic acid, isocaproic acid, β-methylvalerianic acid, tert-butylacetic acid, diethylacetic acid, methyl-n-propylacetic acid, methylisopropylacetic acid, dimethylethylacetic acid, 2-ethylhexanoic acid, etc.

In addition, of saturated fatty acids, there are problems of corrosion and bad smell, and thus, those which are a solid at the ordinary temperature are preferred, and those having a melting point of at least 25° C. are particularly preferred.

### (E-2-2) Unsaturated Carboxylic Acids:

For example, butenoic acid (crotonic acid), butenoic acid (isocrotonic acid), pentenoic acid, angelic acid, tiglic acid, 2-pentenoic acid, 3-pentenoic acid, β-methylcrotonic acid, 2-hexenoic acid, 3-hexenoic acid, 4-hexenoic acid, 5-hexenoic acid, 2-methyl-2-pentenoic acid, α-ethylcrotonic acid, 2-heptenoic acid, 2-octenoic acid, 4-decenoic acid, undecenoic acid, dodecenoic acid, tetradecenoic acid, octadecenoic acid, eicosenoic acid, docosenoic acid, erucic acid, mycolipenic acid, hexadecatrienoic acid, linolic acid, linolenic acid, 6,9,12-octadecatrienoic acid, eicosadienoic acid, eicosatrienoic acid, docosadienoic acid, hexadienoic acid, etc.

### (E-2-3) Aromatic Carboxylic Acids:

For example, benzoic acid, substituted products of toluylbenzoic acid, substituted products of ethylbenzoic acid, substituted products of trimethylbenzoic acid, substituted products of cuminic acid, substituted products of tetramethylbenzoic acid, pentanomethylbenzoic acid, substituted products of hydrocinnamic acid, substituted products of hydroatropic acid, etc.

(E-3) Monohydric Carboxylic Acid Amides (when —X is —CONHR²):

### (E-3-1) Primary Amides:

For example, amino group-substituted primary amides of the carboxylic acids as described above, such as acetamide, formamide, propionamide, butylamide, isobutylamide, valeramide, caproamide, lauramide, palmitoamide, stearylamide, oleamide, benzamide, 2-phenylacetamide, etc.

### (E-3-2) Mono-Substituted Primary Amides:

For example, N-methylacetamide, N-methylethylamide, N-methylpropylamide, N-methylbutylamide, N-methylpentamide, N-methylhexamide, N-methylheptamide, N-methylbenzamide, etc.

(E-4) Monovalent Ketones and Aldehydes (when —X is —COR²):

### (E-4-1) Ketones:

### (E-4-1-1) Aliphatic Ketones;

For example, diethyl ketone, di-n-propyl ketone, diisopropyl ketone, diisobutyl ketone, di-sec-butyl ketone, di-tert-butyl ketone, di-n-amyl ketone, diisoamyl ketone, di-tert-amyl ketone, tetraethyl acetone, di-n-hexyl ketone, di-n-heptyl ketone, di-n-octyl ketone, di-n-nonyl ketone, di-n-undecyl ketone, di-n-tridecyl ketone, di-n-pentadecyl ketone, di-n-heptadecyl ketone, methyl propyl ketone, ethyl propyl ketone, methyl-sec-butyl ketone, methyl-tert-butyl ketone, methyl-n-amyl ketone, methyl-sec-n-amyl ketone, ethyl butyl ketone, methyl-n-hexyl ketone, methyl-b-butyl ketone, methyl-n-nonyl ketone, methyl-n-decyl ketone, methyl-n-undecyl ketone, methyl-n-dodecyl ketone, methyl-n-tridecyl ketone, methyl-n-tetradecyl ketone, methyl-n-pentadecyl ketone, methyl-n-hexadecyl ketone, methyl-n-heptadecyl ketone, etc.

### (E-4-1-2) Aromatic Ketones;

For example, phenyl acetone, benzyl acetone, α-methyl-phenyl acetone, benzyl ketone, chloromethyl benzyl ketone, ω-phenylacetyl acetone, benzophenone, etc.

### (E-4-2) Aldehydes:

### (E-4-2-1) Saturated Aldehydes:

For example, n-valeraldehyde, n-hexaldehyde, n-heptaldehyde, n-undecaldehyde, lauraldehyde, tridecaaldehyde, myristaldehyde, pentadecaldehyde, palmitaldehyde, margaraldehyde,stearylaldehyde, etc.

### (E-4-2-2) Unsaturated Aldehydes:

For example, crotonaldehyde, vinylacetaldehyde, α-methylcrotonaldehyde, β-methylcrotonaldehyde, 2-methyl-pentenal, 2-hexenal, 2,6-dimethyloctadien-(2,6)-al-8, 2,4,6-octatrienal, 2,6,10-trimethyldodecatrien-(1,6,10)-al-(1,2), citral, citroneral, 2,4,6,8-decatetranal, etc.

### (E-4-2-3) Aromatic Aldehydes:

For example, benzaldehyde, 4-methoxybenzaldehyde, 4-butoxybenzaldehyde, 2-ethoxybenzaldehyde, 4-ethoxy-3-methoxybenzaldehyde, 4-ethoxybenzaldehyde, 3-fluorobenzaldehyde, 4-isopropylbenzaldehyde, phenylacetaldehyde, p-methylphenylacetaldehyde, cinnamic aldehyde, p-t-butyl-α-methylhydrocinnamic aldehyde, hexylcinnamic aldehyde, p-methylphenylaldehyde, 2-phenylpropionaldehyde, 3-phenylpropionaldehyde, cuminaldehyde, cyclamen aldehyde, dimethoxybenzaldehyde, p-tolualdehyde, etc.

(E-5) Monovalent Sulfonic Acids (when —X is —SO₃H):

For example, alkylsulfonic acids such as methanesulfonic acid, ethanesulfonic acid, propanesulfonic acid, butanesulfonic acid, pentanesulfonic acid, hexanesulfonic acid, heptanesulfonic acid, octanesulfonic acid, nonanesulfonic acid, decanesulfonic acid, and 1-propene-1-sulfonic acid; alkylbenzenesulfonic acids such as p-toluenesulfonic acid and dodecylbenzenesulfonic acid; alkylnaphthalenesulfonic acids such as naphthalenesulfonic acid, isopropylnapahthalenesulfonic acid, butylnaphthalenesulfonic acid, and isobutylnaphthalenesulfonic acid, etc.

(E-6) Monovalent Sulfonamides (when —X is —SO₂NHR²):

Monovalent sulfonamides by the amino group substitution of the above-described sulfonic acids.

For example, N-n-butyl-p-toluenesulfonamide, N-ethyltoluenesulfonamide, etc.

(E-7) Monovalent Peptides and Ureas (when —X is —HNCONHR²):

### (E-7-1) Peptides:

For example, lactams such as butanelactam, valerolactam, ε-caprolactam, etc.

### (E-7-2) Ureas:

For example, urea, methoxyurea, ethoxyurea, propoxyurea, butoxyurea, ethyleneurea, thiourea, methoxythiourea, ethoxythiourea; propoxythiourea, butoxythiourea, etc.

(E-8) Monourethanes (Carbamic Acid Esters (when —X is —HNCOOR²)):

For example, ethyl N-methylcarbamate, propyl N-phenylcarbamate, naphthyl N-methylcarbamate, ethyl ethoxymethylcarbamate, methylurethane, ethylurethane, propylurethane, butylurethane, benzylurethane, etc.

It is necessary that the component (E) is not volatilized off from the photosensitive layer at drying the photosensitive layer and remains in the photosensitive layer at exposure. From the viewpoints of the above-described points and the smell, etc., the boiling point of the component (E) is preferably at least 95° C., and particularly preferably at least 100° C.

To the negative-working photosensitive resin composition of this invention, if necessary, other additives can be further added. As one of these additives, plasticizers can be used. While there are no particular restrictions on the plasticizers, examples thereof include a compound having a hydroxyl group, such as trimethyloipropane, glycerol, ethylene glycol, diethylene glycol, triethylene glycol, tetraethylene glycol, polyethylene glycol, and propylene glycol. Also, by adding a surfactant, a dye, etc., negative-working photosensitive resin compositions having various functions can be obtained.

The photosensitive resin plate of this invention can be prepared using the photosensitive resin composition of this invention by, for example, the following manners.

That is, the component (A) is first dissolved in a solvent and the components (B) to (E) and other optional additives are added to the solution in an arbitrary order, followed by mixing to provide a photosensitive resin composition liquid.

The photosensitive resin composition liquid is coated on a cover film such as a polyethylene terephthalate film by a coating apparatus such as a curtain coater, a doctor blade coater, a reverse coater, etc., and dried to form a photosensitive layer of from 0.45 to 0.8 mm in thickness.

On the other hand, an adhesive layer is formed on a film base (support) such as a polyester film and heat-treated with a hot plate, etc., to make the adhesive layer in a semi-cured state.

Then, by press-attaching the photosensitive layer on the adhesive layer in a semi-cured state, a photosensitive resin plate (raw plate or to-be-exposed plate) of this invention is produced.

For the adhesive layer, a conventionally known adhesive such as a polyester-based adhesive and an epoxy-based adhesive can be used. Also, the photosensitive layer may be directly formed on a support without using an adhesive layer.

A photocured image-forming process on the photosensitive resin plate (raw plate or to-be-exposed plate) thus obtained can be carried out by an ordinary method, and depending upon the photosensitive resin composition used, the development conditions, the exposure conditions, etc., can be properly changed. Specifically, for example, after releasing the cover film from the surface of the photosensitive layer, the photosensitive layer is exposed through a negative mask using a chemical lamp of an output of about 10-50 W from a distance of 25-50 mm for about 2-15 minutes. Then, the unexposed areas are removed by washing out with a solvent capable of dissolving the unexposed areas using a brush, etc., and the photosensitive layer is then dried at a temperature of 70-90° C. for about 2-10 minutes. Thereafter, if desired, a post exposure is applied for about 5-10 minutes by using the above-described chemical lamp, whereby a photosensitive resin plate having photocured images formed thereon can be obtained.

By using known techniques such as matting of the photosensitive layer, the formation of a slip coat on the surface of the photosensitive layer, or the formation of a sticking prevention layer, etc., together with the technique of this invention, the effects of these known techniques can be effectively obtained in addition to the above-described characteristic effects of this invention.

### Examples

This invention is described specifically by the following Examples, but this invention is not limited to these Examples.

Prior to the Examples, the evaluation methods used in the Examples are shown below.

### [Sensitivity Evaluation]

The sensitivity was evaluated using “Step Tablet No. 2” of Eastman Kodak Corporation by the step number at which a photocured portion was formed.

### [Evaluation of Depth of Non-Printing Area]

The depth was evaluated by the depth (μm) of a non-printing area of independent fine lines of 150 μm.

### [Evaluation of Reproducibility of Highlight Portion]

The reproducibility was evaluated by reproducibility of halftone dots of 3% at 133 lines/inch.

These evaluations were carried out about a printing plate made t an exposure time of 5 minutes and a printing plate made at an exposure time of 10 minutes in order to show the characteristics at the case of much exposure amounts.

### Comparative Example 1

### (1) Preparation of Photosensitive Resin Composition:

In 200 parts by weight of water was dissolved 200 parts by weight of polyvinyl alcohol (degree of saponification: 70%, degree of polymerization: 500) as the component (A), and then, 70 parts by weight of polyethylene glycol diacrylate as the component (B), 4 parts by weight of benzyldimethyl ketal as the component (C), and 0.1 part by weight of methylhydroquinone as the component (D) were added to the solution to prepare a water-soluble photosensitive resin composition.

### (2) Production of Photosensitive Resin Plate:

The above-described water-soluble photosensitive resin composition was coated onto a polyester film (cover film), followed by drying to form a photosensitive layer of 0.7 mm in thickness. Then, a base was adhered thereto to provide a photosensitive resin plate (raw plate or to-be-exposed plate).

### (3) Plate Making:

The cover film was released from the above-described photosensitive resin plate (raw plate or to-be-exposed plate), the photosensitive resin plate was exposed through a mask using a chemical lamp of 20 W from a distance of 45 mm for 5 minutes, and then, the unexposed areas were removed by washing out with water of 35° C. using a brush, followed by drying at 80° C. for 5 minutes to make a printing plate.

Also, by changing the exposure time from 5 minutes to 10 minutes, a printing plate was prepared by the same procedures as above.

For the photosensitive resin plates obtained by the above-described method, the sensitivity evaluation, the non-printing depth evaluation, and the highlight portion reproducibility evaluation described above were carried out. The results are shown in Table 1 below.

### Examples 1-9

By following the same procedures as in Comparative Example 1 except that each of the components (E) described in Table 1 was added, water-soluble photosensitive resin compositions were prepared, and photosensitive resin plates were obtained using each resin composition. The contents of each of the components (E) shown in Table 1 indicate those based on 100 parts by weight of each of the photosensitive resin compositions. For the photosensitive resin plates, the sensitivity evaluation, the non-printing depth evaluation, and the highlight portion reproducibility evaluation described above were carried out. The results are shown in Table 1 below.

### Comparative Example 2

By following the same procedures as in EXAMPLE 1 except that diethylene glycol was used in place of the stearyl alcohol, a water-soluble photosensitive resin composition was prepared, and for a photosensitive resin plate obtained using the resin composition, the sensitivity evaluation, the non-printing depth evaluation, and the highlight portion reproducibility evaluation described above were carried out. The results are shown in Table 1 below.

### Comparative Example 3

By following the same procedures as in EXAMPLE 1 except that tris(2-hydroxyethyl)isocyanurate was used in place of the stearyl alcohol, a water-soluble photosensitive resin composition was prepared, and for a photosensitive resin plate obtained using the resin composition, the sensitivity evaluation, the non-printing depth evaluation, and the highlight portion reproducibility evaluation described above were carried out. The results are shown in Table 1 below.

### Examples 10-12

By following the same procedure as EXAMPLE 1 except that the addition amount of the stearyl alcohol was changed as described in Table 1, water-soluble photosensitive resin compositions were prepared, and photosensitive resin plates were obtained using each of the resin compositions. For the photosensitive resin plate, the sensitivity evaluation, the non-printing depth evaluation, and the highlight portion reproducibility evaluation described above were carried out. The results are shown in Table 1 below.

### Comparative Example 4

By following the same procedures as in EXAMPLE 1 except that the addition amount of the stearyl alcohol was changed as described in Table 1, a water-soluble photosensitive resin composition was prepared, and a photosensitive resin plate was obtained using the resin composition. For the photosensitive resin plate, the sensitivity evaluation, the non-printing depth evaluation, and the highlight portion reproducibility evaluation described above were carried out. The results are shown in Table 1 below.

### Examples 13-29

By following the same procedures as in EXAMPLE 1 except that the component (E) was changed as described in Table 1, water-soluble photosensitive resin compositions were prepared, and photosensitive resin plates were obtained using each of the resin compositions. The content of the component (E) shown in Table 1 indicates the one based on 100 parts by weight of the photosensitive resin composition. For the photosensitive resin plates, the sensitivity evaluation, the non-printing depth evaluation, and the highlight portion reproducibility evaluation described above were carried out. The results are shown in Table 1 below.

### Comparative Example 5

By following the same procedures as in COMPARATIVE EXAMPLE 1 except that the component (A) in COMPARATIVE EXAMPLE 1 was changed to cellulose acetate phthalate and that 200 g of methyl ethyl ketone (MEK) was used in place of 200 g of water, an alkali-soluble photosensitive resin composition was prepared.

Also, by following the same procedure as COMPARATIVE EXAMPLE 1 except that an aqueous solution of 2 wt % sodium carbonate was used in place of water as the washing solution after the exposure, a photosensitive resin plate was produced. For the photosensitive resin plate, the sensitivity evaluation, the non-printing depth evaluation, and the highlight portion reproducibility evaluation described above were carried out. The results are shown in Table 1 below.

### Example 30

By following the same procedures as in COMPARATIVE EXAMPLE 5 except that the component (E) described in Table 1 was added, an alkali-soluble photosensitive resin composition was prepared, and a photosensitive resin plate was obtained using the resin composition. The content of the component (E) shown in Table 1 indicates the one based on 100 parts by weight of the photosensitive resin composition. For the photosensitive resin plate, the sensitivity evaluation, the non-printing depth evaluation, and the highlight portion reproducibility evaluation described above were carried out. The results are shown in Table 1 below.

### Comparative Example 6

By following the same procedures as in COMPARATIVE EXAMPLE 1 except that the component (A) in COMPARATIVE EXAMPLE 1 was changed to nylon 8 phthalate and that 200 g of methanol was used in place of 200 g of water, an alcohol-soluble photosensitive resin composition was prepared.

Also, by following the same procedures as in COMPARATIVE EXAMPLE 1 except that a methanol solution was used in place of water as the washing solution after the exposure, a photosensitive resin plate was produced. For the photosensitive resin plate, the sensitivity evaluation, the non-printing depth evaluation, and the highlight portion reproducibility evaluation described above were carried out. The results are shown in Table 1 below.

### Example 31

By following the same procedures as in COMPARATIVE EXAMPLE 6 except that the component (E) described in Table 1 was added, an alcohol-soluble photosensitive resin composition was prepared, and a photosensitive resin plate was obtained using the resin composition. The content of the component (E) shown in Table 1 indicates the one based on 100 parts by weight of the photosensitive resin composition. For the photosensitive resin plate, the sensitivity evaluation, the non-printing depth evaluation, and the highlight portion reproducibility evaluation described above were carried out. The results are shown in Table 1 below.

TABLE 1

| | | Addition | Exposure Time | | | | | |
|---|---|---|---|---|---|---|---|---|
| | | Amount of | 5 minutes | | | 10 minutes | | |
| | | Component | Step | Depth (μm) | Reproducibility | Step | Depth (μm) | Reproducibility |
| | Component (E) | (E) | Number | (*1) | (*2) | Number | (*1) | (*2) |
| Comparative | — | 0 | 14 | 39 | Good | 16 | 20 | Good |
| Example 1 | | | | | | | | |
| Example 1 | Stearyl alcohol | 0.047 | 14 | 43 | Good | 16 | 39 | Good |
| Example 2 | Diethylene glycol mono- | 0.047 | 14 | 42 | Good | 16 | 35 | Good |
| | methyl ether | | | | | | | |
| Example 3 | Diethylene glycol mono- | 0.047 | 14 | 42 | Good | 16 | 34 | Good |
| | ethyl ether | | | | | | | |
| Example 4 | 2-Ethyl-1-hexanol | 0.047 | 14 | 43 | Good | 16 | 38 | Good |
| Example 5 | Tetrahydrofurfuryl alcohol | 0.047 | 14 | 42 | Good | 16 | 36 | Good |
| Example 6 | 2,2-Dimethylpropanol | 0.047 | 14 | 42 | Good | 16 | 37 | Good |
| Example 7 | 2-Phenoxyethanol | 0.047 | 14 | 42 | Good | 16 | 38 | Good |
| Example 8 | n-Hexanol | 0.047 | 14 | 43 | Good | 16 | 38 | Good |
| Example 9 | Oleyl alcohol | 0.047 | 14 | 40 | Good | 16 | 38 | Good |
| Comparative | Diethylene glycol | 0.047 | 14 | 42 | Good | 16 | 19 | Good |
| Example 2 | | | | | | | | |
| Comparative | Tris(2-hydroxyethyl) iso- | 0.047 | 14 | 43 | Good | 16 | 15 | Good |
| Example 3 | cyanurate | | | | | | | |
| Example 10 | Stearyl alcohol | 0.001 | 14 | 40 | Good | 16 | 24 | Good |
| Example 11 | Stearyl alcohol | 0.01 | 14 | 41 | Good | 16 | 38 | Good |
| Example 12 | Stearyl alcohol | 0.3 | 14 | 40 | Good | 16 | 24 | Good |
| Comparative | Stearyl alcohol | 0.4 | 14 | 41 | Good | 16 | 15 | Good |
| Example 4 | | | | | | | | |
| Example 13 | Stearic acid | 0.047 | 14 | 40 | Good | 16 | 39 | Good |
| Example 14 | 2-Ethylhexanoic acid | 0.047 | 14 | 41 | Good | 16 | 41 | Good |
| Example 15 | Benzoic acid | 0.047 | 14 | 42 | Good | 16 | 42 | Good |
| Example 16 | Acetamide | 0.047 | 14 | 40 | Good | 16 | 39 | Good |
| Example 17 | Di-n-amyl ketone | 0.047 | 14 | 41 | Good | 16 | 38 | Good |
| Example 18 | Di-n-heptadecyl ketone | 0.047 | 14 | 40 | Good | 16 | 39 | Good |
| Example 19 | Methyl-n-hexyl ketone | 0.047 | 14 | 42 | Good | 16 | 38 | Good |
| Example 20 | Methyl-n-undecyl ketone | 0.047 | 14 | 41 | Good | 16 | 39 | Good |
| Example 21 | p-Toluenesulfonic acid | 0.047 | 14 | 43 | Good | 16 | 40 | Good |
| Example 22 | N-n-Butyl-p-toluene- | 0.047 | 14 | 42 | Good | 16 | 41 | Good |
| | sulfonamide | | | | | | | |
| Example 23 | N-Ethyltoluenesulfon- | 0.047 | 14 | 40 | Good | 16 | 40 | Good |
| | amide | | | | | | | |
| Example 24 | ε-Caprolactam | 0.047 | 14 | 43 | Good | 16 | 40 | Good |
| Example 25 | Urea | 0.047 | 14 | 42 | Good | 16 | 36 | Good |
| Example 26 | Thiourea | 0.047 | 14 | 41 | Good | 16 | 36 | Good |
| Example 27 | Benzyl ethyl ether | 0.047 | 14 | 42 | Good | 16 | 35 | Good |
| Example 28 | Ethyl-n-hexyl ether | 0.047 | 14 | 42 | Good | 16 | 35 | Good |
| Example 29 | Benzyl urethane | 0.047 | 14 | 40 | Good | 16 | 39 | Good |
| Comparative | — | 0 | 14 | 38 | Good | 16 | 18 | Good |
| Example 5 | | | | | | | | |
| Example 30 | Oleyl alcohol | 0.047 | 14 | 39 | Good | 16 | 38 | Good |
| Comparative | — | 0 | 14 | 38 | Good | 16 | 16 | Good |
| Example 6 | | | | | | | | |
| Example 31 | Di-n-amyl ketone | 0.047 | 14 | 38 | Good | 16 | 35 | Good |

(*1): Non-printing depth of 150 μm is shown.
(*2): Reproducibility of the halftone dots of 3% at 133 lines/inch is shown.

As shown in Table 1, it has been confirmed that each of the negative-working photosensitive resin compositions of this invention has the reproducibility of halftone dots of 3% at 133 lines/inch of at least 90% and is excellent in the reproducibility of the highlight areas.

Also, in the sensitivity evaluation and the non-printing depth evaluation, the results of the deep depth and the excellent resolving properties were obtained while having the sensitivity almost the same as those of the Comparative Examples.

Furthermore, from the evaluations of changing the exposure time from 5 minutes to 10 minutes, it has been confirmed that even when the exposure time is prolonged, the photosensitive resin compositions of this invention have the deep depth and are excellent in the resolving properties.

Also, when the prints obtained by using the printing plates prepared in the Comparative Examples were compared with the prints obtained by using the printing plates prepared by the Examples of this invention, in the case of using the printing plates of the Examples, the prints having clear non-printing areas and having good quality as compared with the prints in the Comparative Examples could be obtained.

As mentioned above in detail, according to this invention, a water-soluble, alkali-soluble or alcohol-soluble negative-working photosensitive resin composition which is useful for producing a photosensitive resin plate for printing utilized for various printing fields is obtained. Also, by using the resin composition, the production of a photosensitive resin plate, which is excellent in the reproducibility of the highlight areas and the independent fine lines, has a deep non-printing depth, and has good resolving properties, becomes possible.

What is claimed is:

1. A photosensitive resin plate comprising a support having formed thereon directly or via an adhesive layer a photosensitive layer of from 0.45 to 0.8 mm in thickness comprising a negative working photosensitive resin composition consisting essentially of
(A) a film-forming polymer,
(B) an unsaturated compound having a radical polymerizable ethylenic double bond,
(C) a photopolymerization initiator in an amount of 0.5-5 wt % based on the weight of the photosensitive resin composition components (A) to (E),
(D) a thermal polymerization inhibitor, and
(E) at least one member selected from compounds represented by following formula (I):
R¹—X (I)
wherein —X represents —OR², —COOH, —CONHR², —COR², —HNCONHR², or —HNCOOR²; R¹ and R², which may be the same or different, each represents a hydrogen atom, a substituted or unsubstituted, saturated or unsaturated hydrocarbon group, provided that it does not contain a radical polymerizable ethylenic double bond, a substituted or unsubstituted alicyclic hydrocarbon group, a substituted or unsubstituted aromatic hydrocarbon group, or a heterocyclic group, wherein said hydrocarbon group, alicyclic hydrocarbon group, aromatic hydrocarbon group, or the heterocyclic group may have an ether bond in the chain, provided that when —X is —OH, the R¹ represents a group other than a hydrogen atom and an aromatic hydrocarbon group, provided that component (E) is not benzophenone and is different from component (C), in an amount of from 0.001 to 0.3% by weight based on the weight of the photosensitive resin composition components (A) to (E).

2. The photosensitive resin plate as claimed in claim 1, wherein the compound represented by the formula (I) has a boiling point of at least 95° C.

3. The photosensitive resin plate as claimed in claim 1, wherein the component (A) is at least one member selected from water-soluble polymers, alkali-soluble polymers, and alcohol-soluble polymers.

4. A photosensitive resin plate having formed thereon photocured images obtained by selectively exposing the photosensitive layer on the photosensitive resin plate as claimed in claim 1 through a mask pattern, developing, and forming the photocured images by removing the unexposed areas.
